(19) United States
(12) Patent Application Publication
(10) Pub. No.: US 2023/0014567 A1
(43) Pub. Date: Jan. 19, 2023

(54) PACKAGE SUBSTRATE EMPLOYING INTEGRATED SLOT-SHAPED ANTENNA(S), AND RELATED INTEGRATED CIRCUIT (IC) PACKAGES AND FABRICATION METHODS

(71) Applicant: QUALCOMM Incorporated, San Diego, CA (US)

(72) Inventors: Jaehyun Yeon, San Diego, CA (US); Kun Fang, San Diego, CA (US); Suhyung Hwang, Rancho Mission Viejo, CA (US); Hyunchul Cho, Suwon (KR)

(21) Appl. No.: 17/375,289

(22) Filed: Jul. 14, 2021

(51) Int. Cl. H01Q 1/22; H01Q 13/10; H01L 23/498; H01L 23/552; H01L 23/66; H01L 21/48

(52) U.S. Cl. CPC H01Q 1/2283; H01Q 13/10; H01L 23/49822; H01L 23/49838; H01L 23/552; H01L 23/66; H01L 21/4857; H01L 2223/6677

(57) ABSTRACT

Package substrates employing integrated slot-shaped antenna(s), and related integrated circuit (IC) packages and fabrication methods. The package substrate can be provided in a radio-frequency (RF) IC (RFIC) package. The package substrate includes one or more slot-shaped antennas each formed from a slot disposed in the metallization substrate that can be coupled to the RFIC die for receiving and radiating RF signals. The slot-shaped antenna includes a conductive slot disposed in at least one metallization layer in the package substrate. A metal interconnect in a metallization layer in the package substrate is coupled to the conductive slot to provide an antenna feed line for the slot-shaped antenna. In this manner, the slot-shaped antenna being integrated into the metallization substrate of the IC package can reduce the area in the IC package needed to provide an antenna and/or provide other directions of antenna radiation patterns for enhanced directional RF performance.

### BACKGROUND

### 1. Field of the Disclosure

The field of the disclosure relates to radio-frequency (RF) integrated circuit (IC) (RFIC) packages that include a RF transceiver and antenna module supported by a package substrate.

### II. BACKGROUND

Modem smart phones and other portable devices have extended the use of different wireless links with a variety of technologies in different radio frequency bands. For example, fifth generation (5G) cellular networks, commonly referred to as 5G new radio (NR) include frequencies in the range of 24.25 to 86 Gigahertz (GHz), with the lower 19.25 GHz (24.25-43.5 GHz) more likely to be used for mobile devices. This frequency spectrum of 5G communications is in the range of millimeter wave (mmWave) or millimeter band. mmWave enables higher data rates than at lower frequencies, such as those used for Wi-Fi and current cellular networks.

Radio-frequency (RF) transceivers that support mmWave spectrum are incorporated into mobile and other portable devices that are designed to support mmWave communications signals. To support the integration of a RF transceiver in a device, the RF transceiver can be integrated in RF integrated circuit (IC) (RFIC) transceiver chips (“RFIC chips”) that are provided as part of an RFIC package. A conventional RFIC package includes one or more RFIC chips, a power management IC (PMIC), and passive electrical components (e.g., inductors, capacitors, etc.) mounted to one side of a package substrate as a support structure. The package substrate supports metallization structures to provide chip-to-chip and external signal interfaces to the RFIC chip(s). The RFIC package can also include an antenna module that is part of the package substrate. The antenna module can include one or more antennas that can receive and radiate electrical RF signals as electromagnetic (EM) signals. The antenna module may include a plurality of antennas, also referred to an antenna array, to provide a signal coverage in a desired, larger area around the RFIC package. The antenna elements in the antenna array of the antenna module are coupled through one or more metallization structures in the package substrate to the RFIC chip(s).

It may be desired to minimize the area consumed by antennas in an antenna module of a RFIC package to reduce the overall size of the RFIC package. However, the antenna module also needs to have a sufficient radiation pattern to achieve the desired RF performance depending on the desired application. For example, a patch antenna is a low profile antenna that can be employed in an antenna module of a RFIC package. However, the radiation pattern of a patch antenna may be predominantly in the direction of a plane of its “patch.” As another example, a dipole antenna is an antenna with two conducting wires of half-wavelength of the maximum desired wavelength that can also be employed in an antenna module of a RFIC package. However, the radiation pattern of a dipole antenna may be predominantly in the direction perpendicular to the antenna poles. Thus, it may be required to provide different types of antennas in the RFIC package and in different areas to achieve the desired directional RF performance, but at a cost of increased RFIC package size and complexity. Also, if the RFIC package is used for multiple input, multiple output (MIMO) communication applications, further additional antennas must be provided in the antenna module of the RFIC package to support the multiple MIMO signal streams thus further increasing RFIC package size in an undesired manner.

### SUMMARY OF THE DISCLOSURE

Aspects disclosed in the detailed description include package substrates employing integrated slot-shaped antenna(s). Related integrated circuit (IC) packages and fabrication methods are also disclosed. The package substrate can be provided as part of an IC package that includes a radio-frequency (RF) IC (RFIC) die(s) in a RFIC chip for supporting RF communications as an example. For example, the RFIC die may be provided in an IC die layer that is coupled to the package substrate. The package substrate includes one or more metallization layers that each include metal interconnects for routing of signals with the RFIC die. For example, the package substrate may include a coreless metallization substrate that includes or more metallization layers. In exemplary aspects, the package substrate includes one or more slot-shaped antennas each formed from a slot disposed in one or more metallization layers of the package substrate and that can be coupled to the RFIC die for receiving and radiating RF signals. The slot-shaped antenna includes a conductive slot disposed in at least one metallization layer in the package substrate. As an example, the conductive slot may extend fully through the package substrate and in a direction orthogonal to the plane of the metallization layers in the package substrate. To form the conductive slot, a slot can be formed in the metallization layer(s) thereby forming one or more internal side walls in the metallization layer(s) within the slot. A metal material can then be disposed on the internal side wall(s) of the slot to form one or more separate antenna elements in the slot that are not physically coupled to each other. Thus, the separate antenna elements formed within the slot may be similar to patch antennas in structure and design. A metal interconnect in a metallization layer in the package substrate is coupled to the conductive slot to provide an antenna feed line for the slot-shaped antenna. For example, the slot being disposed in the metallization layer(s) in the package substrate can expose a side wall of metal interconnects that will be conductively coupled to the conductive slot as a result of the metal material being disposed on an inside side wall of the slot to form an antenna feed line. The antenna element coupled to the antenna feed line can be electromagnetically coupled to other antenna elements formed in the conductive slot to provide the slot-shaped antenna.

In this manner, the slot-shaped antenna(s) being integrated into a slot(s) disposed in the package substrate of the IC package can reduce the area in the IC package needed to provide an antenna. For example, integrating the slot-shaped antenna(s) in the package substrate may eliminate the need to provide a separate antenna substrate in the IC package that contains antenna elements for providing an antenna. Alternatively, the slot-shaped antenna(s) disposed in the package substrate can be employed to provide additional antenna elements in addition to antenna elements provided in an antenna substrate in the IC package. For example, integrating the slot-shaped antenna in a slot disposed in the package substrate can facilitate an orientation that is orthogonal to the orientation of other patch antennas included in a separate antenna substrate to support radiation patterns in different desired directions to achieve the directional RF performance.

In this regard, in one exemplary aspect, a package substrate is provided. The package substrate comprises one or more metallization layers each comprising one or more metal interconnects. The package substrate also comprises a slot-shaped antenna. The slot-shaped antenna comprises a conductive slot disposed in at least one metallization layer among the one or more metallization layers, and at least one antenna feed line comprising at least one metal interconnect among the one or more metal interconnects coupled to the conductive slot.

In another exemplary aspect, a method of forming an integrated slot-shaped antenna in a package substrate is provided. The method comprises forming one or more metallization layers each comprising one or more metal interconnects. The method also comprises forming a conductive slot disposed in at least one metallization layer among the one or more metallization layers to form a slot-shaped antenna. The method comprises coupling at least one antenna feed line comprising at least one metal interconnect among the one or more metal interconnects of the at least one metallization layer coupled to the conductive slot.

In another exemplary aspect, an integrated circuit (IC) package is provided. The IC package comprises a package substrate. The package substrate comprises one or more metallization layers each comprising one or more metal interconnects. The package substrate also comprises a slot-shaped antenna. The slot-shaped antenna comprises a conductive slot disposed in at least one substrate metallization layer among the one or more substrate metallization layers, and at least one antenna feed line comprising at least one metal interconnect among the one or more metal interconnects coupled to the conductive slot. The IC package also comprises an IC die layer coupled to the package substrate, the IC die layer comprising a radio-frequency (RF) IC (RFIC) die comprising a plurality of die interconnects. At least one die interconnect among the plurality of die interconnects is coupled to the at least one antenna feed line of the slot-shaped antenna.

### BRIEF DESCRIPTION OF THE FIGURES

FIGS. 1A and 1B are respective side and bottom views of a radio-frequency (RF) integrated circuit (IC) (RFIC) package that includes an antenna substrate supporting patch and dipole antenna elements;

FIGS. 2A and 2B are respective side and bottom views of an RFIC package that includes a package substrate having one or more integrated slot-shaped antennas to support RF signal communications;

FIGS. 2C and 2D are close-up, cross-sectional side views of the package substrate in FIG. 2A that further illustrates slot-shaped antennas formed by respective conductive slots disposed through the package substrate;

FIG. 3 is a side view of a slot-shaped antenna formed by a conductive slot disposed through the package substrate in FIG. 2D;

FIG. 4 is a flowchart illustrating an exemplary process for fabricating a slot-shaped antenna, such as the slot-shaped antennas in FIGS. 2A-2D, formed by disposing a conductive slot in the package substrate and coupling the conductive slot to a respective metal interconnect in a metallization layer as an antenna feed line;

FIGS. 5A-5E illustrate exemplary fabrication stages during fabrication of a package substrate having integrated slot-shaped antennas, including, but not limited to, the package substrate in FIGS. 2A-2D;

FIGS. 6A and 6B are a flowchart illustrating an exemplary process for fabricating a package substrate having integrated slot-shaped antennas, including, but not limited to, the package substrate in FIGS. 2A-2D and according to the fabrication stages in FIGS. 5A-5E;

FIG. 7 is a block diagram of an exemplary wireless communications device that includes RF components provided in one or more RFIC packages employing a package substrate having integrated slot-shaped antennas, including, but not limited to, the package substrate in FIGS. 2A-2D, and according to any of the fabrication processes in FIGS. 4-6B; and

FIG. 8 is a block diagram of an exemplary processor-based system that includes RF components provided in one or more RFIC packages employing a package substrate having integrated slot-shaped antennas, including, but not limited to, the package substrate in FIGS. 2A-2D, and according to any of the fabrication processes in FIGS. 4-6B.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include package substrates employing integrated slot-shaped antenna(s). Related integrated circuit (IC) packages and fabrication methods are also disclosed. The package substrate can be provided as part of an IC package that includes a radio-frequency (RF) IC (RFIC) die(s) in a RFIC chip for supporting RF communications as an example. For example, the RFIC die may be provided in an IC die layer that is coupled to the package substrate. The package substrate includes one or more metallization layers that each include metal interconnects for routing of signals with the RFIC die. For example, the package substrate may include a coreless metallization substrate that includes or more metallization layers. In exemplary aspects, the package substrate includes one or more slot-shaped antennas each formed from a slot disposed in one or more metallization layers of the package substrate and that can be coupled to the RFIC die for receiving and radiating RF signals. The slot-shaped antenna includes a conductive slot disposed in at least one metallization layer in the package substrate. As an example, the conductive slot may extend fully through the package substrate and in a direction orthogonal to the plane of the metallization layers in the package substrate. To form the conductive slot, a slot can be formed in the metallization layer(s) thereby forming one or more internal side walls in the metallization layer(s) within the slot. A metal material can then be disposed on the internal side wall(s) of the slot to form one or more separate antenna elements in the slot that are not physically coupled to each other. Thus, the separate antenna elements formed within the slot may be similar to patch antennas in structure and design. A metal interconnect in a metallization layer in the package substrate is coupled to the conductive slot to provide an antenna feed line for the slot-shaped antenna. For example, the slot being disposed in the metallization layer(s) in the package substrate can expose a side wall of metal interconnects that will be conductively coupled to the conductive slot as a result of the metal material being disposed on an inside side wall of the slot to form an antenna feed line. The antenna element coupled to the antenna feed line can be electromagnetically coupled to other antenna elements formed in the conductive slot to provide the slot-shaped antenna.

In this manner, the slot-shaped antenna(s) being integrated into a slot(s) disposed in the package substrate of the IC package can reduce the area in the IC package needed to provide an antenna. For example, integrating the slot-shaped antenna(s) in the package substrate may eliminate the need to provide a separate antenna substrate in the IC package that contains antenna elements for providing an antenna. Alternatively, the slot-shaped antenna(s) disposed in the package substrate can be employed to provide additional antenna elements in addition to antenna elements provided in an antenna substrate in the IC package. For example, integrating the slot-shaped antenna in a slot disposed in the package substrate can facilitate an orientation that is orthogonal to the orientation of other patch antennas included in a separate antenna substrate to support radiation patterns in different desired directions to achieve the directional RF performance.

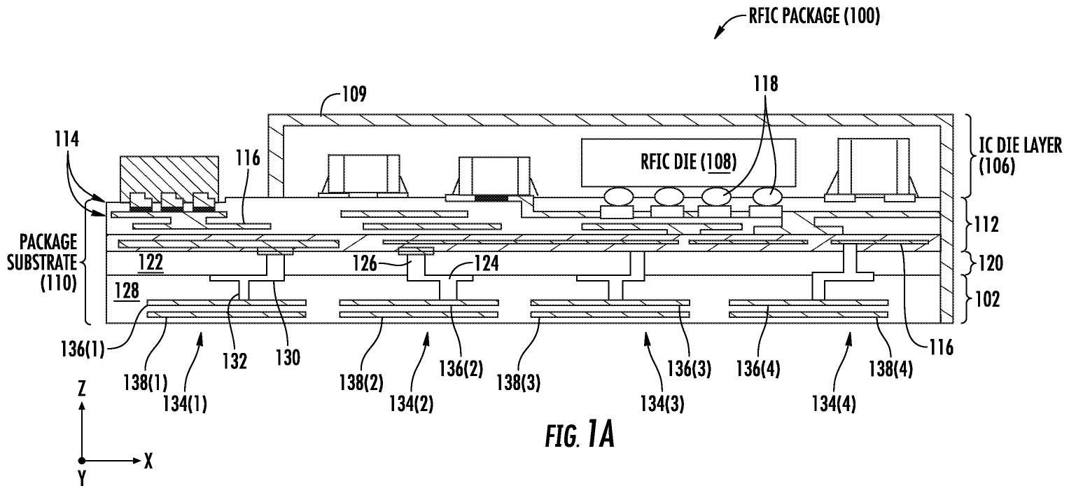

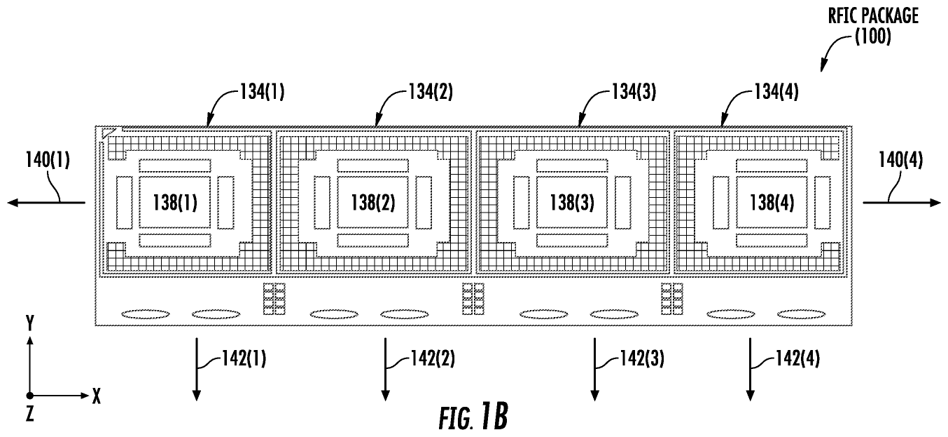

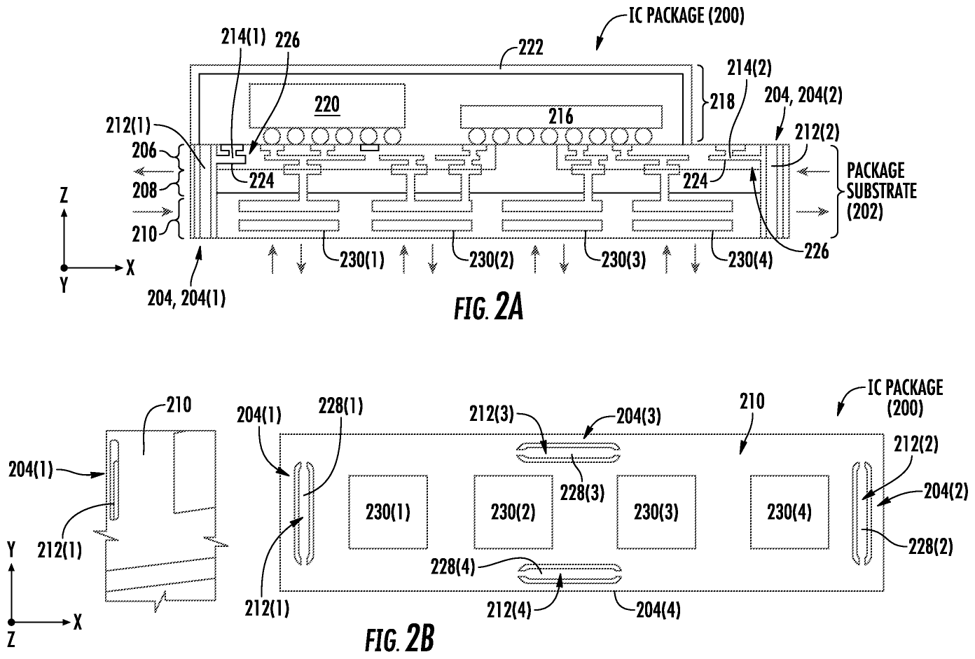

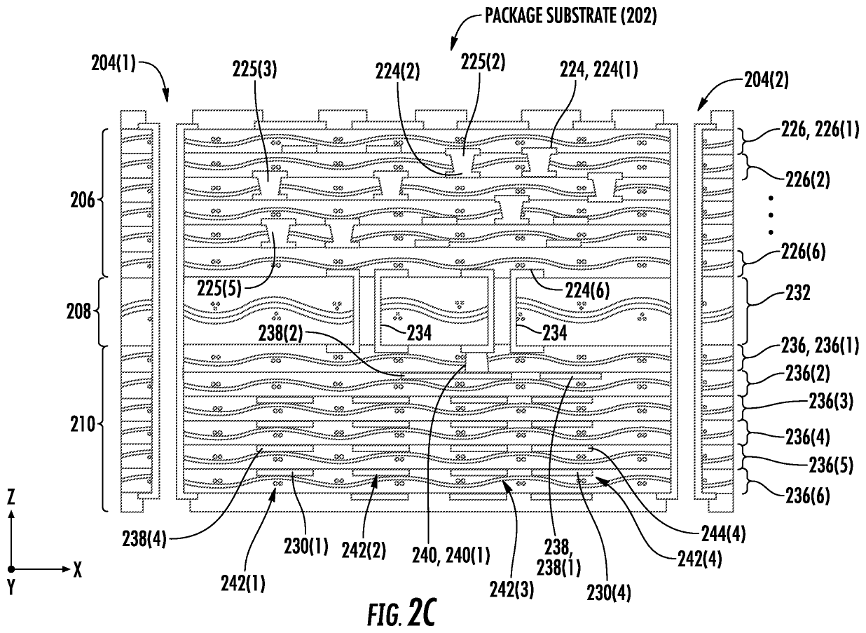

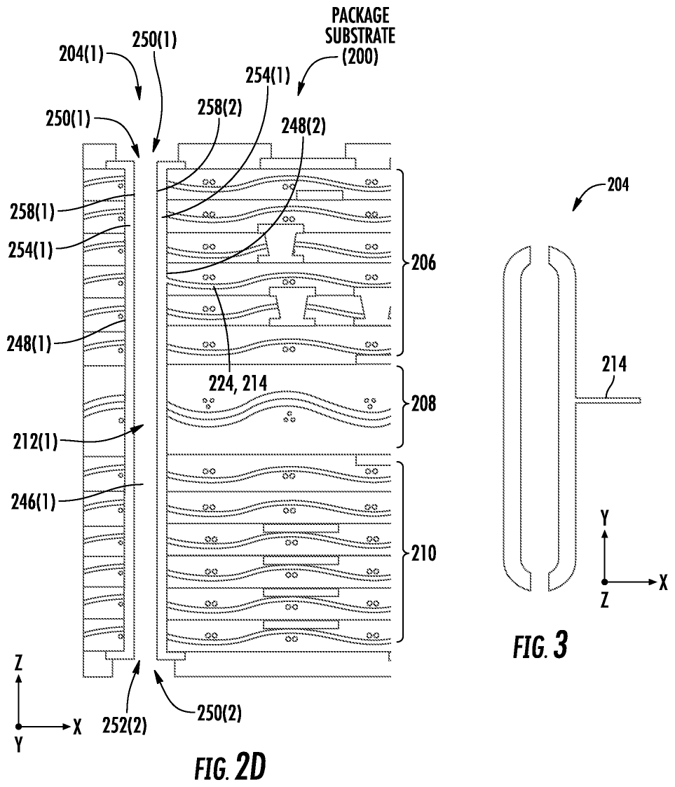

Before discussing IC packages that include a package substrate that includes one or more integrated slot-shaped antennas formed by respective conductive slots disposed in the package substrate to support RF communications, an IC package in the form of a RFIC package 100 that does not include integrated slot-shaped antennas in its package substrate is first described with regard to FIGS. 1A and 1B. An example of IC package that includes a package substrate that includes one or more integrated slot-shaped antennas formed by respective conductive slots disposed in the package substrate to support RF communications is discussed below starting at FIG. 2A.

In this regard, FIGS. 1A and 1B are respective side and bottom views of a RFIC package 100 that includes an antenna substrate 102 supporting patch and dipole antenna elements for supporting RF communications. As shown in FIG. 1A, the RFIC package 100 includes an IC die layer 106 disposed in a horizontal X-Y horizontal plane and that includes an RFIC die 108 that includes an encapsulated RF transceiver IC(s). The RFIC die 108 could also include a power management IC (PMIC). The IC die layer 106 is mounted to a package substrate 110 to provide a support structure for the IC die layer 106 and to also provide an interconnect structure for coupling the RFIC die 108 to other components and circuits in the RFIC package 100. An electromagnetic interference (EMI) shield 109 is disposed around the RFIC die 108 and other components in the IC die layer 106. In this example, the package substrate 110 includes a metallization substrate 112 that is adjacent to the IC die layer 106. The metallization substrate 112 includes a plurality of substrate metallization layers 114 that each include metal interconnects 116 (e.g., pads, vertical interconnect accesses (vias), traces, lines) formed therein for providing interconnection structures to facilitate interconnections to provide an electrical interface between the RFIC die 108 and other components and circuits in the RFIC package 100. Die interconnects 118 couple the RFIC die 108 to the metal interconnects 116 in the metallization substrate 112. The metallization substrate 112 may be a coreless substrate. The substrate metallization layers 114 could be formed as separate substrate layers that laminated together to form the metallization substrate 112. One or more of the substrate metallization layers 114 could also be formed as redistribution layers (RDLs). In this example, the metallization substrate 112 is coupled to a core substrate 120 as part of the package substrate 110. A core substrate, such as the core substrate 120, is a substrate that is typically thicker and is made from a dielectric material that is stiff to prevent or reduce warpage in the RFIC package 100. The core substrate 120 also includes one or more metallization layers 122 that include metal interconnects 124 coupled to vertical interconnect accesses (vias) 126 (e.g., metal pillars) coupled to metal interconnects 116 in the adjacent metallization substrate 112 to provide electrical connectivity between the metallization substrate 112 and the core substrate 120.

With continuing reference to FIG. 1A, the package substrate 110 in the RFIC package 100 also includes the antenna substrate 102. The antenna substrate 102 is coupled to the core substrate 120 such that the core substrate 120 is disposed between the antenna substrate 102 and the metallization substrate 112 in the Z-axis direction in this example. The antenna substrate 102 also includes one or more metallization layers 128 that include metal interconnects 130 coupled to vias 132 coupled to metal interconnects 124 in the core substrate 120. The antenna substrate 102 includes four (4) antenna elements 134(1)-134(4) in this example that are electrically coupled to the RFIC die 108 through interconnections between the antenna elements 134(1)-134(4) and the metal interconnects 116, 124, 130 in the respective metallization substrate 112, core substrate 120 and antenna substrate 102. In this example, each antenna element 134(1)-134(4) includes a dipole antenna 136(1)-136(4) adjacent to the core substrate 120 and a patch antenna 138(1)-138(4) disposed below the respective dipole antennas 136(1)-136(4). This is to provide different directional RF performance. For example, the patch antennas 138(10)-138(4) may be low profile structures that have respective radiation pattern directions 140(1)-140(4) predominantly in the X-axis direction in the RFIC package 100, as shown in FIG. 1B. The radiation pattern direction 142(1)-142(4) of the dipole antennas 136(1)-136(4) may be predominantly in the Y-axis direction in the RFIC package 100 as shown in FIG. 1B. However, neither the dipole antennas 136(1)-136(4) nor the patch antenna 138(1)-138(4) may provide a radiation pattern oriented in the Z-axis direction of the RFIC package 100. Thus, this may require that additional antenna elements be disposed in other areas of the RFIC package 100 not shown to provide the desired RF directional performance. However, this may come at a cost of increased RFIC package 100 size and complexity, which may be undesired or infeasible for certain applications.

FIGS. 2A and 2B are respective side and bottom views of an exemplary IC package 200 that includes a package substrate 202 having one or more integrated slot-shaped antennas 204 to support RF signal communications. In this example, as shown in FIGS. 2A and 2B, four (4) slot-shaped antennas 204(1)-204(4) are disposed in and integrated in the package substrate 202. For example, the slot-shaped antennas 204(1)-204(4) may be designed for millimeter wave (mmWave) reception, including RF signals in the fifth generation (5G) new radio (NR) spectrum. Note that the IC package 200 is not limited to having less or more than four (4) of the slot-shaped antennas 204. In this example, the slot-shaped antennas 204(1)-204(4) are disposed in and through the metallization substrate 206, core substrate 208, and antenna substrate 210 of the package substrate 202. In this example, the slot-shaped antennas 204(1)-204(4) are formed from a respective conductive slot 212(1)-212(4) disposed in the metallization substrate 206, core substrate 208, and antenna substrate 210 that is coupled through a respective antenna feed line 214(1), 214(2) (see FIG. 2A) to an RFIC die 216 to support RF communications. In an example, the conductive slot is a physical slot (e.g., an aperture) disposed in a substrate(s) of a given internal width (e.g., internal diameter or distance) and that is typically elongated in a length direction orthogonal to the internal width or diameter. A metal material is disposed at least partially on one or more internal side walls or surfaces of the slot to form a conductive slot. For example, the slot may be a cylindrical-shaped aperture with an internal diameter with a metal material disposed on at least a portion(s) of the internal wall of the aperture. In this example, the slot-shaped antennas 204(1), 204(2) formed from the conductive slots 212(1), 212(2) are elongated in the Y-axis direction as compared to the X-axis direction as shown in FIG. 2A. The slot-shaped antennas 204(3), 204(3) are elongated in the X-axis direction orthogonal to the elongation direction of the slot-shaped antennas 204(1), 204(2) in this example. The RFIC die 216 can radiate a RF signal through the antenna feed lines 214(1)-214(4) to the respective conductive slots 212(1)-212(4) to radiate the RF signal over-the-air external from the IC package 200.

As shown in FIG. 2A, the RFIC package 200 in this example includes an IC die layer 218 disposed in a horizontal X-Y horizontal plane and that includes the RFIC die 216 in an IC chip that includes an encapsulated RF transceiver IC(s). The IC die layer 218 could also include a PMIC die 220 in an IC chip. The IC die layer 218 is mounted to or formed on the package substrate 202 to provide a support structure for the IC die layer 218 and to also provide an interconnect structure for coupling the RFIC die 216 and the PMIC die 220 to other components and circuits in the IC package 200. An EMI shield 222 is disposed around the RFIC die 216 and PMIC die 220 in the IC die layer 218.

The antenna feed lines 214(1), 214(2) shown in FIG. 2A in this example are metal interconnects 224 (e.g., pads, vertical interconnect accesses (vias), traces, metal lines) formed in a substrate metallization layer 226 (also referred to as “metallization layer 226”) in the metallization substrate 206. In this example, the conductive slots 212(1)-212(4) extend fully through the package substrate 202 including the metallization layer 226 in a direction shown as the Z-axis direction orthogonal to the X-Y axis planes of the metallization substrate 206, core substrate 208, and the antenna substrate 210. As will be discussed in more detail below, and as shown in the bottom view of the IC package 200 in FIG. 2B, the conductive slots 212(1)-212(4) being formed of slots 228(1)-228(4) separate antenna elements that are not physically coupled to each other. The separate antenna elements formed within the slot may be similar to patch antennas in structure and design. A metal interconnect 224 as a respective antenna feed line 214(1), 214(2) shown in FIG. 2A is coupled to one of the antenna elements of the conductive slots 212(1), 212(2), which can be electromagnetically coupled to other antenna elements formed in its respective conductive slots 212(1), 212(2) to provide the slot-shaped antennas 204(1), 204(2).

In this manner, the slot-shaped antennas 204(1)-204(4) being integrated into the package substrate 202, including the metallization substrate 206, of the IC package 200 can reduce the area in the IC package 200 needed to provide an antenna. For example, integrating the slot-shaped antennas 204(1)-204(4) in the package substrate 202 could eliminate the need to provide a separate antenna substrate, like antenna substrate 210, in the IC package 200 to provide an antenna. Alternatively, as shown in the IC package 200 in FIGS. 2A and 2B, the slot-shaped antennas 204(1)-204(4) in the package substrate 202 can be employed to provide additional antenna elements in addition to antenna elements provided in the antenna substrate 210 in the IC package 200. For example, integrating the slot-shaped antennas 204(1)-204(4) in the package substrate 202 can facilitate an orientation (e.g., a Y- and Z-axis orientation) that is orthogonal to the orientation (e.g., X- and Y-axis orientation) of other patch antennas 230(1)-230(4) included in the antenna substrate 210 to support radiation patterns in different desired directions to achieve the directional RF performance.

FIG. 2C is a close-up, cross-sectional, side view of the package substrate 202 in FIG. 2A that illustrates further exemplary detail of the package substrate 202 and slot-shaped antennas 204 formed in the package substrate 202. The package substrate 202 includes the metallization substrate 206 that is adjacent to the IC die layer 218 in FIG. 2A. The metallization substrate 206 includes a plurality of substrate metallization layers 226 that each include respective conductive metal interconnects 224 (e.g., pads, vertical interconnect accesses (vias), traces, metal lines) formed therein for providing conductive interconnection structures to facilitate interconnections to provide an electrical interface between the RFIC die 216 and other components and circuits in the IC die layer 218 in the IC package 200 in FIG. 2A. Vias 225(1)-225(6) are formed in the respective substrate metallization layers 226(1)-226(6) to provide interconnections between their metal interconnects 224(1)-224(6). In this example, the metallization substrate 206 includes six (6) substrate metallization layers 226(1)-226(6) that each include respective metal interconnects 224(1)-224(6) to facilitate electrical interconnections between the core substrate 208 and the IC die layer 218. The metallization substrate 206 may be a coreless substrate. The substrate metallization layers 226(1)-226(6) could be formed as separate substrate layers that laminated together to form the metallization substrate 206. One or more of the substrate metallization layers 226(1)-226(6) could also be formed as RDLs. In this example, the metallization substrate 206 is coupled to the core substrate 208. A core substrate, such as core substrate 208, is a substrate that is typically thicker and is made from a dielectric material that is stiff to prevent or reduce warpage. The core substrate 208 also includes one or more core metallization layers 232 (also referred to as “metallization layers 232”) that may also include metal interconnects coupled to vias 234 (e.g., metal pillars) coupled to metal interconnects 224(6) in the adjacent substrate metallization layer 226(6) of the metallization substrate 206 to provide electrical connectivity between the metallization substrate 206 and the core substrate 208.

With continuing reference to FIG. 2C, the package substrate 202 in this example also includes the optional antenna substrate 210. The antenna substrate 210 is coupled to the core substrate 208 such that the core substrate 208 is disposed between the antenna substrate 210 and the metallization substrate 206 in the Z-axis direction in this example. The antenna substrate 210 also includes or more metallization layers 236 that each include metal interconnects 238 (e.g., pads, vertical interconnect accesses (vias), traces, metal lines) that can be coupled to vias 240, 240(1) and coupled to vias 234 in the core substrate 208. In this example, the antenna substrate 210 includes six (6) metallization layers 236(1)-236(6). In this example, the antenna substrate 210 includes four (4) antenna elements 242(1)-242(4) that are electrically coupled to the RFIC die 216 in FIG. 2A through interconnection between the antenna elements 242(1)-242(4) and the metal interconnects 238(1)-238(6), the vias 234 in the core substrate 208, and the metal interconnects 224(1)-224(6) in the metallization substrate 206. In this example, each antenna element 242(1)-242(4) includes a dipole antenna 244(1)-244(4) disposed in the metallization layer 236(5) as a substrate antenna layer adjacent to the core substrate 208. The antenna elements 242(1)-242(4) also include the patch antennas 230(1)-230(4) disposed in the metallization layer 236(6) as an substrate antenna layer disposed adjacent to and below the respective dipole antennas 244(1)-244(4) in the Z-axis direction. This is to provide different directional RF performance. For example, the patch antenna 230(1)-230(4) may be low profile structures that have a respective radiation pattern direction predominantly in the X-axis direction, as shown in FIG. 2C. The radiation pattern direction of the dipole antennas 244(1)-244(4) may be predominantly in the Y-axis direction as shown in FIG. 2C. However, neither the dipole antennas 244(1)-244(4) nor the patch antennas 230(1)-230(4) may provide a radiation pattern oriented in the Z-axis direction of the package substrate 202 like provided by the slot-shaped antennas 204(1)-204(4).

FIG. 2D is another close-up, cross-sectional, side view of the package substrate 202 in FIGS. 2A and 2C to illustrate and discuss further exemplary detail of the slot-shaped antennas 204(1)-204(4) in the IC package 200 in FIG. 2A. Note that in FIG. 2D, only slot-shaped antenna 204(1) is shown. However, the discussion below with regard to the exemplary details of the slot-shaped antenna 204(1) can also apply equally to the slot-shaped antennas 204(2)-204(4) in FIG. 2B.

In this regard, with reference to FIG. 2D and using slot-shaped antenna 204(1) as an example, the slot-shaped antenna 204(1) includes the conductive slot 212(1) that is formed from a slot 246(1) that extends through the entire package substrate 202 in this example. This is also shown in the top view of the conductive slot 212(1) in FIG. 3. The slot 246(1) extends through the metallization substrate 206, the core substrate 208, and the antenna substrate 210 in the Z-axis direction in this example. The slot 246(1) is elongated in the height or Z-axis direction as shown in FIG. 2D, orthogonal to the plane (X-Y plane) of the metallization layers 226 in the metallization substrate 206. As shown in FIG. 3, the slot 246(1) is also elongated in the depth or Y-axis, which is parallel to the plane (X-Y plane) of the metallization layers 226 in the metallization substrate 206. Thus, the slot 246(1) is elongated in a Y-Z plane as shown in FIGS. 2D and 3. Note however, that it is not required that the slot 246(1) extend through the entire package substrate 202 including each of the substrate metallization layers 226(1)-226(6) of the metallization substrate 206, the core metallization layer 232 of the core substrate 208, and/or each of the metallization layers 236(1)-236(6) of the antenna substrate 210. For example, the slot 246(1) extending through the entire package substrate 202 could extend only through a portion or whole of the metallization layers 226, 232, 236 of the metallization substrate 206, core substrate 208, and/or the antenna substrate 210. The slot 246(1) being formed in the package substrate 202 forms side walls 248(1), 248(2) in this example. This is a result of the slot 246(1) extending in the Z-axis direction through the entire package substrate 202 forming first and second openings 250(1), 250(2) at opposite sides of each other in the package substrate 202 at a first end 252(1) and a second end 252(2) of the slot 246(1) opposite the first end 252(1). Opening 250(1) is formed in the metallization substrate 206, and the second opening 250(2) is formed in the antenna substrate 210 as a result of forming the slot 246(1) through the package substrate 202 in this example. A metal material 254(1), 254(2) is disposed on the respective side walls 248(1), 248(2) formed from the formation of the slot 246(1) through the package substrate 202 to form conductive side walls 258(1), 258(2). For example, the metal material 254(1), 254(2) could be copper. Also, as an example, a metal plating material, such as a NiAu, could also be plated on the metal material 254(1), 254(2) to protect the metal material 254(1), 254(2) surface from oxidation. The metal material 254(1) does not contact metal material 254(2) in this example, and is a result of the slot 246(1) being an open slot with openings 250(1), 205(2) that separate the side walls 248(1), 248(2). The conductive side walls 258(1), 258(2) form respective antenna elements 260(1), 260(2) that are like patch antennas in this example. For example, when the metal material 254(1), 254(2) is disposed on the respective side walls 248(1), 248(2), curved metal patch-like antenna elements 260(1), 260(2) (shown in FIG. 3) are formed on each side of the slot 246(1) in this example that extends in the Z-axis direction through the package substrate 202.

When the slot 246(1) is formed in the package substrate 202, a metal interconnect 224, such as in the metallization substrate 206, may be exposed. The metallization substrate 206 can be designed so that the metal interconnect 224 is proximate to and exposed to the side wall 248(2) when the slot 246(1) is formed. In this manner, the metal material 254(2) disposed on the side wall 248(2) will be conductively coupled to the exposed metal interconnect 224 such that the metal interconnect 224 can form an antenna feed line 214. The metal interconnect 224 as the antenna feed line 214 can then be conductively coupled through the metallization substrate layers 226 and to a RFIC die 216 in FIG. 2A for example. In this manner, the conductive slot 212(1) forms an antenna for the RFIC die 216. In this example, the metal material 254(1) of the antenna element 260(1) is not directly in contact with the metal interconnect 224 as the antenna feed line 214. This is also shown in the top view of the conductive slot 212(1) in FIG. 3. However, the antenna element 260(1) being adjacent to the antenna element 260(2) formed by the conductive slot 212(1) can be electromagnetically (EM) coupled to the antenna element 260(2) when the antenna element 260(2) is energized by a current from the RFIC die 216 for example. In this manner, the antenna elements 260(1), 260(2) of the conductive slot 212(1) form an antenna that can be coupled through the metallization substrate 206 to the RFIC die 216 without having to dispose a separate antenna element in an antenna substrate, like the antenna substrate 210 in FIG. 2D.

Note that although the package substrate 202 includes the separate antenna substrate 210, such is not required. The separate antenna substrate 210 is provided in this example, as previously discussed, to support other antennas. Also note that in this example, the conductive slot 212(1) extends through each of the metallization substrate 206, the core substrate 208, and the antenna substrate 210. Such is not required. The conductive slot 212(1) could be disposed partially in the package substrate 202. For example, the conductive slot 212(1) could be disposed partially or fully into one or more of the metallization substrate 206, the core substrate 208, and the antenna substrate 210. Also, the antenna feed line 214 could be provided as a metal interconnect in the core substrate 208 or a metal interconnect 234 in the antenna substrate 210. Further, the conductive slot 212(1) could have multiple antenna feed lines formed from metal interconnects 224, 234 in the metallization substrate 206, the core substrate 208, and/or the antenna substrate 210.

There are various manners in which a slot-shaped antenna integrated into a package substrate, such as the slot-shaped antennas 204(1)-204(4) integrated in the package substrate 202 in the IC package 200 in FIGS. 2A-2D, can be formed and fabricated. FIG. 4 is a flowchart illustrating an exemplary process 400 for fabricating a slot-shaped antenna, such as the slot-shaped antennas 204(1)-204(4), integrated in a package substrate, such as the package substrate 202 in the IC package 200 in FIGS. 2A-2D. The process 400 in FIG. 4 is discussed with regard to the package substrate 202 in FIGS. 2A-2D as an example.

In this regard, the process 400 includes forming one or more metallization layers 226(1)-226(6), 232, 236(1)-236(6) each comprising one or more respective metal interconnects 224, 234, 238 (block 402 in FIG. 4). Note that the formed metallization layers can include metallization layers from any or all of the metallization layers 226(1)-226(6), 232, 236(1)-236(6) in the respective metallization substrate 206, core substrate 208, and antenna substrate 210. The process 400 then includes forming a conductive slot 212 disposed in at least one metallization layer 226, 232, 236 among the one or more substrate metallization layers 226(1)-226(6), 232, 236(1)-236(6) to form a slot-shaped antenna 204 (block 404 in FIG. 4). The process 400 then includes coupling at least one antenna feed line 214 comprising at least one metal interconnect 224 among the one or more metal interconnects 224 of the at least one metallization layer 226, 232, 236, to the conductive slot 212 (block 406 in FIG. 4).

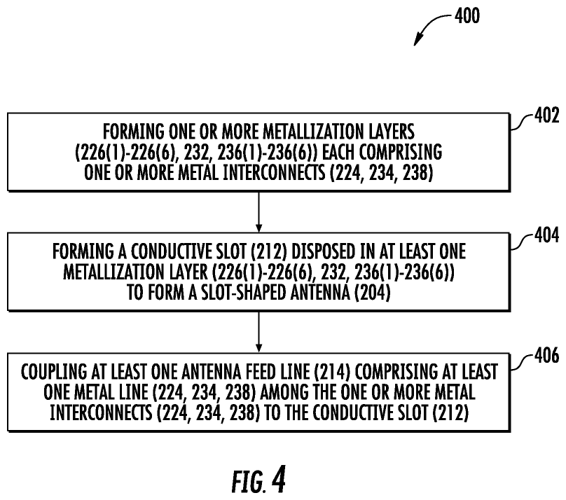

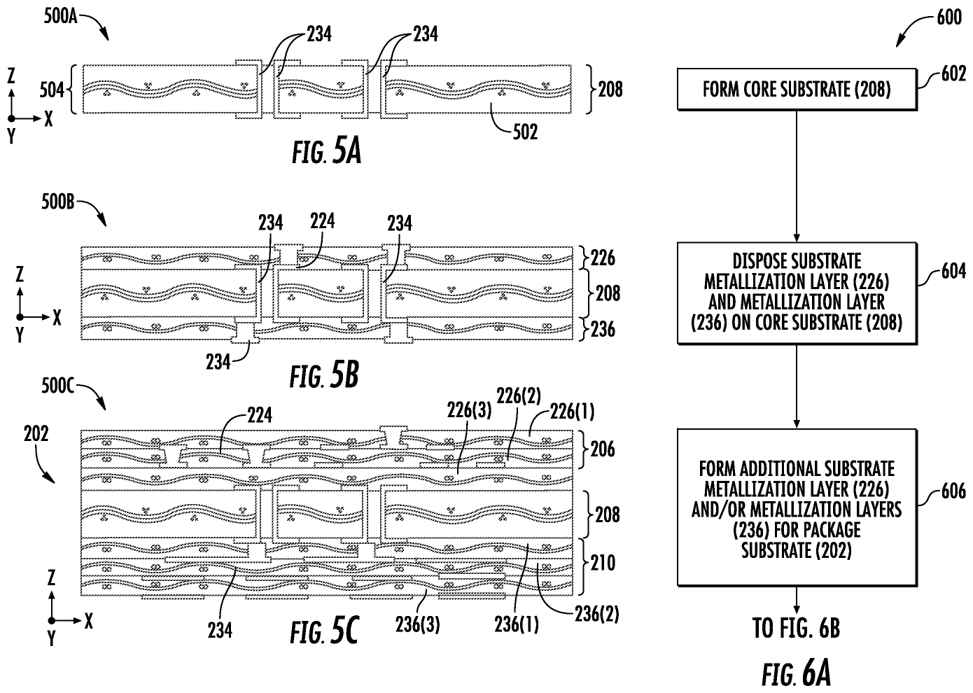

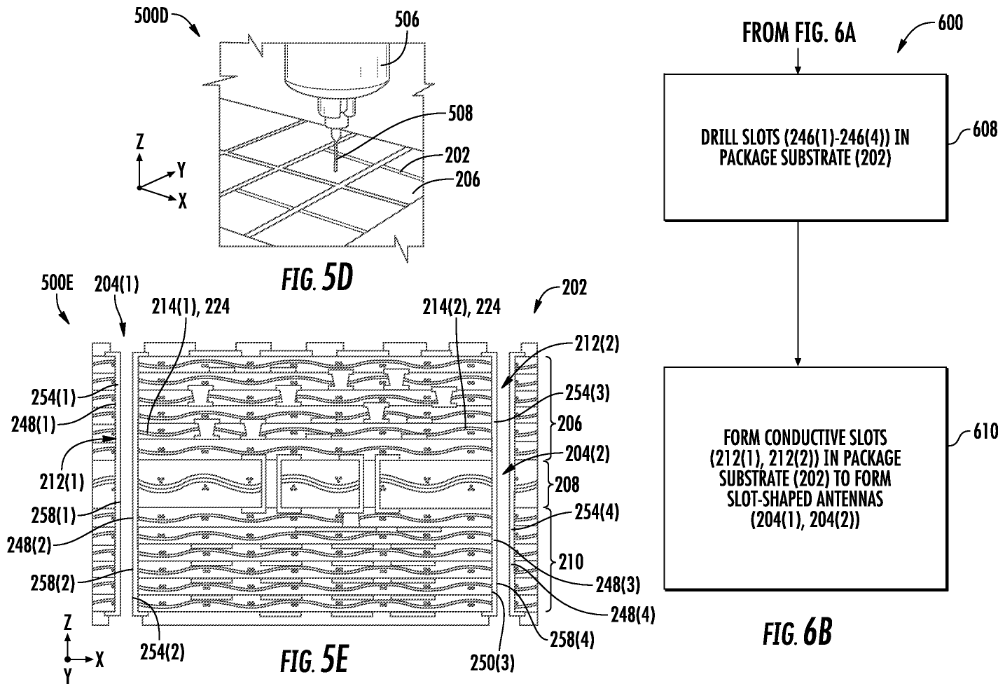

Other fabrication methods are also possible. For example, FIGS. 5A-5E illustrate exemplary fabrication stages 500A-500E, respectively, during fabrication of a package substrate having integrated slot-shaped antennas, including, but not limited to, the slot-shaped antennas 204(1)-204(4) in the package substrate 202 in FIGS. 2A-2D. FIGS. 6A and 6B are a flowchart illustrating an exemplary process 600 for fabricating a package substrate having integrated slot-shaped antennas according to the fabrication stages 500A-500E in FIGS. 5A-5E. The fabrication stages 500A-500E in FIGS. 5A-5E according to the exemplary fabrication process 600 in FIGS. 6A-6B will now be discussed in regard to the package substrate 202 in FIGS. 2A-2D as an example.

In this regard, a first exemplary step in the process 600 in FIG. 6A is to form the core substrate 208 (block 602 in FIG. 6A). This is shown in the exemplary fabrication stage 500A in FIG. 5A. The core substrate 208 can be formed of a strong dielectric material 502 in a dielectric layer 504 that has a desired stiffness to resist bending or warpage. The metal interconnects 234 are formed in the dielectric layer 504 to support metal interconnects with other substrates that are disposed in contact with the core substrate 208.

In a next exemplary step in the process 600 in FIG. 6A, substrate metallization layers 226 and metallization layers 236 of the respective metallization substrate 206 and the antenna substrate 210 are formed on the core substrate 208 as shown in the exemplary fabrication stage 500B in FIG. 5B (block 604 in FIG. 6A). Additional substrate metallization layers 226(2), 226(3) and metallization layers 236(2), 236(3) are formed on prior formed substrate metallization layers 226 and metallization layers 236 on the core substrate 208 until the metallization substrate 206 and antenna substrate 210 are formed of the desired number of substrate metallization layers 226 and metallization layers 236 as shown in fabrication stage 500C (block 606 in FIG. 6C). Any number of substrate metallization layers 226 and metallization layers 236 can be formed as desired to form the metallization substrate 206 and antenna substrate 210. For example, the metallization layers 226 and metallization layers 236 of the metallization substrate 206 and antenna substrate 210 may be formed as separate layers that are formed and laminated to the core substrate 208 and/or to each other. Alternatively, some or all of the metallization layers 226 and metallization layers 236 can be formed by formation of RDLs.

A next exemplary step in the process 600 involves the formation of the slots 246(1)-246(4) in the package substrate 202 formed by the process steps 602-606 in FIG. 6A as shown in the fabrication stages 500A-500C in FIGS. 5A-5C. As previously discussed, the slots 246(1)-246(4) are formed in and/or through the package substrate 202 in the Z-axis direction in this example to form the conductive slots 212(1)-212(4) to form integrated antenna elements to provide antennas in the IC package 200. As shown in the fabrication stage 500D in FIG. 5D, the slots 246(1)-246(4) may be formed by drilling openings into the package substrate 202 with a drill 506 (block 608 in FIG. 6B). A drill bit 508 of the drill 506 can be aligned with the desired location of the slots 246(1)-246(4) to be formed in the package substrate 202. The drill 506 can then be powered to cause the drill bit 508 to be rotated downward into the package substrate 202 to form the slots 246(1)-246(4) in the package substrate 202.

Then, as previously discussed, and as shown in the fabrication stage 500E in FIG. 5B, the conductive slots 212(1), 212(2) are formed in the package substrate (block 610 in FIG. 6B). In the package substrate 202 in FIGS. 2A-2D, there are actually four (4) conductive slots 212(1)-212(4). However, only conductive slots 212(1), 212(2) are shown in the fabrication stage 500E in FIG. 5E. A metal material 254(1)-254(4) is disposed in the conductive slots 212(1), 212(2) to form conductive side walls 258(1)-258(4). For example, the metal material 254(1)-254(4) could be copper. Also, as an example, a metal plating material 510(1)-510(4), such as a NiAu, could also be plated on the respective metal material 254(1)-254(4) to protect the metal material 254(1)-254(4) surface from oxidation. When the slots 246(1), 246(2) are formed in the package substrate 202, a metal interconnect 224, such as in the metallization substrate 206, may be exposed. The metallization substrate 206 can be designed so that the metal interconnect 224 is proximate to and exposed to the side walls 248(2), 248(3) when the slots 246(1), 246(2) are formed. In this manner, the metal material 254(2), 254(3) disposed on the side walls 248(2), 248(3) will be conductively coupled to the exposed metal interconnect 224 such that the metal interconnect 224 can form antenna feed lines 214(1), 214(2). In this manner, the conductive slots 212(1), 212(2) form the slot-shaped antennas 204(1), 204(2) for the RFIC die 216 in FIG. 2A.

Note that the slot-shaped antenna(s) discussed above can be formed and disposed in a slot disposed in any metallization layer of a package substrate, such as the package substrate 202 in FIG. 2A. The slot-shaped antenna(s) can be formed and disposed in the metallization substrate adjacent to an IC die layer, such as IC die layer 218, a core substrate, such as core substrate 208, and an antenna substrate, such as antenna substrate 210.

Package substrates having one or more integrated slot-shaped antennas that can be provided in an IC package, including a RFIC package, to support RF signal communications, including, but not limited to, the package substrates in FIGS. 2A-2D, and according to any of the fabrication processes in FIGS. 4-6B, may be provided in or integrated into any wireless communication device and/or processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

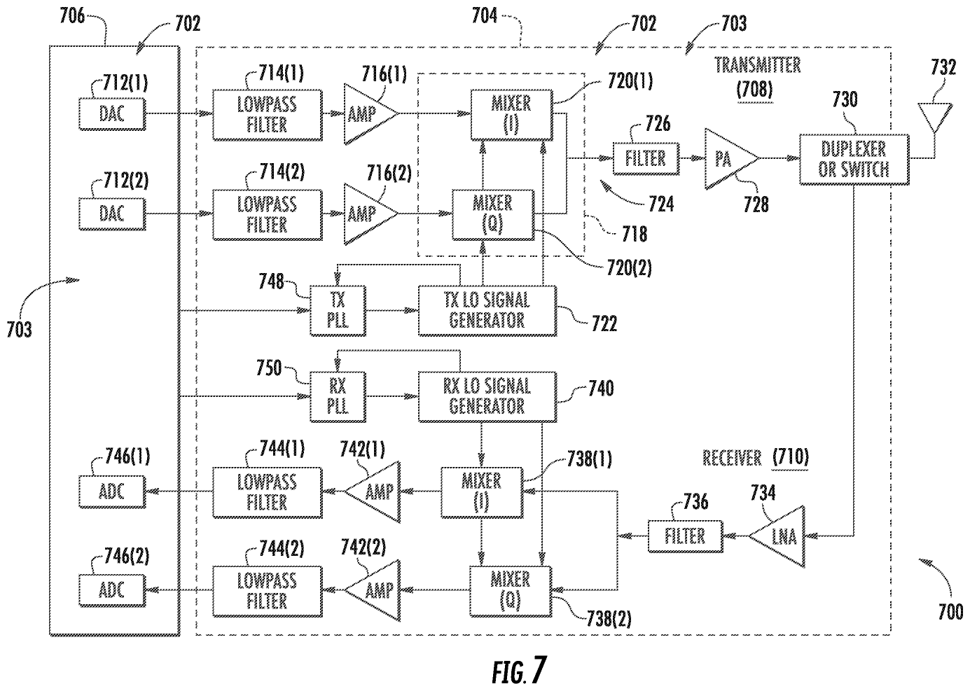

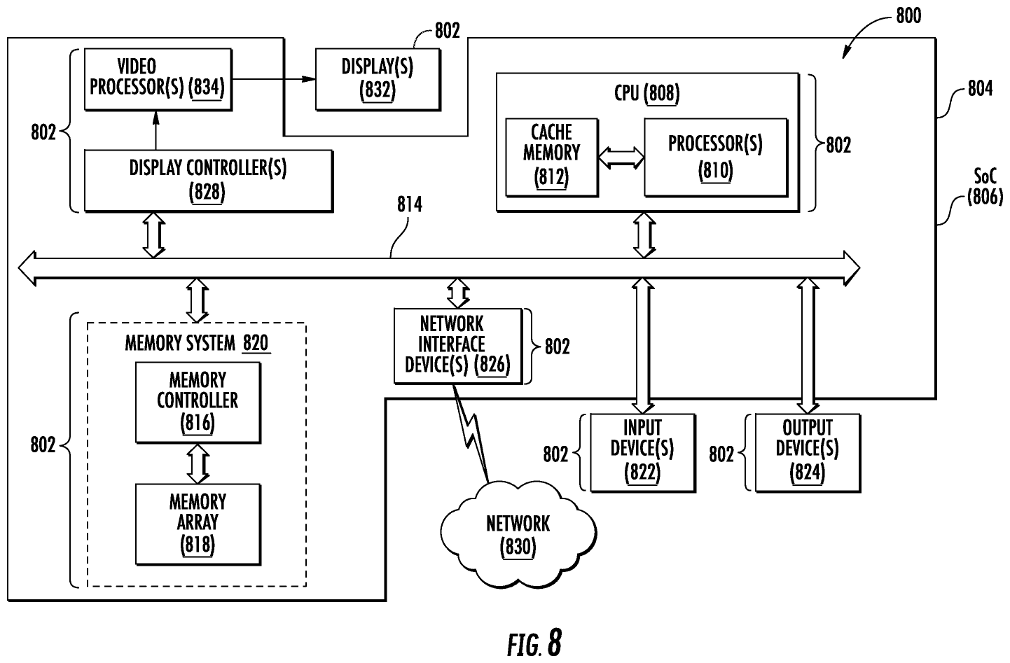

FIG. 7 illustrates an exemplary wireless communications device 700 that includes RF components formed from one or more ICs 702, wherein any of the ICs 702 can be included in an RFIC package 703 employing a package substrate having one or more integrated slot-shaped antennas to support RF signal communications, including, but not limited to, the package substrates in FIGS. 2A-2D, and according to any of the fabrication processes in FIGS. 4-6B. The wireless communications device 700 may include or be provided in any of the above-referenced devices, as examples. As shown in FIG. 7, the wireless communications device 700 includes a transceiver 704 and a data processor 706. The data processor 706 may include a memory to store data and program codes. The transceiver 704 includes a transmitter 708 and a receiver 710 that support bi-directional communications. In general, the wireless communications device 700 may include any number of transmitters 708 and/or receivers 710 for any number of communication systems and frequency bands. All or a portion of the transceiver 704 may be implemented on one or more analog ICs, RFICs, mixed-signal ICs, etc.

The transmitter 708 or the receiver 710 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 710. In the direct-conversion architecture, a signal is frequency-converted between RF and baseband in one stage. The super-heterodyne and direct-conversion architectures may use different circuit blocks and/or have different requirements. In the wireless communications device 700 in FIG. 7, the transmitter 708 and the receiver 710 are implemented with the direct-conversion architecture.

In the transmit path, the data processor 706 processes data to be transmitted and provides I and Q analog output signals to the transmitter 708. In the exemplary wireless communications device 700, the data processor 706 includes digital-to-analog converters (DACs) 712(1), 712(2) for converting digital signals generated by the data processor 706 into the I and Q analog output signals, e.g., I and Q output currents, for further processing.

Within the transmitter 708, lowpass filters 714(1), 714(2) filter the I and Q analog output signals, respectively, to remove undesired signals caused by the prior digital-to-analog conversion. Amplifiers (AMPs) 716(1), 716(2) amplify the signals from the lowpass filters 714(1), 714(2), respectively, and provide I and Q baseband signals. An upconverter 718 upconverts the I and Q baseband signals with I and Q transmit (TX) local oscillator (LO) signals through mixers 720(1), 720(2) from a TX LO signal generator 722 to provide an upconverted signal 724. A filter 726 filters the upconverted signal 724 to remove undesired signals caused by the frequency upconversion as well as noise in a receive frequency band. A power amplifier (PA) 728 amplifies the upconverted signal 724 from the filter 726 to obtain the desired output power level and provides a transmit RF signal. The transmit RF signal is routed through a duplexer or switch 730 and transmitted via an antenna 732.

In the receive path, the antenna 732 receives signals transmitted by base stations and provides a received RF signal, which is routed through the duplexer or switch 730 and provided to a low noise amplifier (LNA) 734. The duplexer or switch 730 is designed to operate with a specific receive (RX)-to-TX duplexer frequency separation, such that RX signals are isolated from TX signals. The received RF signal is amplified by the LNA 734 and filtered by a filter 736 to obtain a desired RF input signal. Downconversion mixers 738(1), 738(2) mix the output of the filter 736 with I and Q RX LO signals (i.e., LO_I and LO_Q) from an RX LO signal generator 740 to generate I and Q baseband signals. The I and Q baseband signals are amplified by AMPs 742(1), 742(2) and further filtered by lowpass filters 744(1), 744(2) to obtain I and Q analog input signals, which are provided to the data processor 706. In this example, the data processor 706 includes analog-to-digital converters (ADCs) 746(1), 746(2) for converting the analog input signals into digital signals to be further processed by the data processor 706.

In the wireless communications device 700 of FIG. 7, the TX LO signal generator 722 generates the I and Q TX LO signals used for frequency upconversion, while the RX LO signal generator 740 generates the I and Q RX LO signals used for frequency downconversion. Each LO signal is a periodic signal with a particular fundamental frequency. A TX phase-locked loop (PLL) circuit 748 receives timing information from the data processor 706 and generates a control signal used to adjust the frequency and/or phase of the TX LO signals from the TX LO signal generator 722. Similarly, an RX PLL circuit 750 receives timing information from the data processor 706 and generates a control signal used to adjust the frequency and/or phase of the RX LO signals from the RX LO signal generator 740.

FIG. 8 illustrates an example of a processor-based system 800. The components of the processor-based system 800 are ICs 802. Some or all of the ICs 802 in the processor-based system 800 can be provided as an IC package 804 employing a package substrate having one or more integrated slot-shaped antennas to support RF signal communications, including, but not limited to, the package substrates in FIGS. 2A-2D, and according to any of the fabrication processes in FIGS. 4-6B, and according to any aspects disclosed herein. In this example, the processor-based system 800 may be formed as an IC package 804 as a system-on-a-chip (SoC) 806. The processor-based system 800 includes a CPU 808 that includes one or more processors 810, which may also be referred to as CPU cores or processor cores. The CPU 808 may have cache memory 812 coupled to the CPU 808 for rapid access to temporarily stored data. The CPU 808 is coupled to a system bus 814 and can intercouple master and slave devices included in the processor-based system 800. As is well known, the CPU 808 communicates with these other devices by exchanging address, control, and data information over the system bus 814. For example, the CPU 808 can communicate bus transaction requests to a memory controller 816 as an example of a slave device. Although not illustrated in FIG. 8, multiple system buses 814 could be provided, wherein each system bus 814 constitutes a different fabric.

Other master and slave devices can be connected to the system bus 814. As illustrated in FIG. 8, these devices can include a memory system 820 that includes the memory controller 816 and a memory array(s) 818, one or more input devices 822, one or more output devices 824, one or more network interface devices 826, and one or more display controllers 828, as examples. Each of the memory system 820, the one or more input devices 822, the one or more output devices 824, the one or more network interface devices 826, and the one or more display controllers 828 can be provided in the same or different IC packages. The input device(s) 822 can include any type of input device, including, but not limited to, input keys, switches, voice processors, etc. The output device(s) 824 can include any type of output device, including, but not limited to, audio, video, other visual indicators, etc. The network interface device(s) 826 can be any device configured to allow exchange of data to and from a network 830. The network 830 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 826 can be configured to support any type of communications protocol desired.

The CPU 808 may also be configured to access the display controller(s) 828 over the system bus 814 to control information sent to one or more displays 832. The display controller(s) 828 sends information to the display(s) 832 to be displayed via one or more video processors 834, which processes the information to be displayed into a format suitable for the display(s) 832. The display controller(s) 828 and video processor(s) 834 can be included as IC package 804 and the same or different IC packages, and in the same or different IC packages containing the CPU 808 as an example. The display(s) 832 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered aspects/clauses.

1. A package substrate, comprising:
one or more metallization layers each comprising one or more metal interconnects; and
a slot-shaped antenna, comprising:
   a conductive slot disposed in at least one metallization layer among the one or more metallization layers; and
   at least one antenna feed line comprising at least one metal interconnect among the one or more metal interconnects coupled to the conductive slot.
      2. The package substrate of clause 1, wherein the conductive slot is configured to radiate a radio-frequency (RF) signal received from the at least one antenna feed line.
      3. The package substrate of any of clauses 1 and 2, wherein:
the conductive slot comprises:
   a slot comprising at least one side wall disposed in the at least one metallization layer; and
   a metal material disposed on the at least one side wall; and
the at least one metal interconnect of the one or more metal interconnects of the at least one metallization layer is coupled to the metal material.
   4. The package substrate of clause 3, wherein the slot is elongated along an axis parallel to a plane of the at least one metallization layer;
the conductive slot configured to radiate a radio-frequency (RF) signal in a direction orthogonal to a direction of the elongation of the slot.
   5. The package substrate of any of clauses 1 to 4, wherein:
the conductive slot comprises a slot comprising:
   a first conductive side wall, comprising:
      a first side wall disposed in the at least one metallization layer; and
      a first metal material disposed on the first side wall; and
   a second conductive side wall, comprising:
      a second side wall disposed in the at least one metallization layer adjacent to the first side wall; and
      a second metal material disposed on the second side wall; and
the at least one metal interconnect of the one or more metal interconnects of the at least one metallization layer is coupled to the first metal material.
   6. The package substrate of clause 5, wherein the first metal material is not physically coupled to the second metal material.
   7. The package substrate of any of clauses 5 and 6, wherein the second conductive side wall is configured to be electromagnetically coupled to the first conductive side wall in response to a radio-frequency (RF) signal.
   8. The package substrate of any of clauses 1 to 7, wherein the conductive slot comprises:
a first end disposed adjacent to a first opening in the one or more metallization layers; and
a second end opposite the first end, the second end adjacent to a second opening in the one or more metallization layers.
   9. The package substrate of any of clauses 1 to 8, wherein:
the one or more metallization layers are each elongated in a first axis; and
the conductive slot is disposed in the least one metallization layer in a direction orthogonal to the first axis.
   10. The package substrate of any of clauses 1 to 9, wherein:
the one or more metallization layers comprise a plurality of metallization layers; and
the conductive slot is disposed in at least two (2) metallization layers among the plurality of metallization layers.
   11. The package substrate of any of clauses 1 to 10, wherein:
the one or more metallization layers comprise a plurality of metallization layers; and
the conductive slot is disposed through each metallization layer among the plurality of metallization layers.
   12. The package substrate of any of clauses 1 to 11, further comprising a metallization substrate comprising the one or more metallization layers each comprising the one or more metal interconnects.
   13. The package substrate of clause 12, further comprising a core substrate disposed adjacent to the metallization substrate,
the core substrate comprising a core metallization layer comprising one or more metal interconnects coupled to the one or more metal interconnects in the metallization substrate.
   14. The package substrate of any of clauses 12 and 13, further comprising an antenna substrate comprising one or more antenna elements each coupled to a metal interconnect among the one or more metal interconnects in the metallization substrate.
   15. The package substrate of clause 14, wherein the one or more antenna elements comprise one or more patch antennas.
   16. The package substrate of clause 14, wherein the one or more antenna elements comprise one or more dipole antennas.
   17. The package substrate of clause 14, wherein the one or more antenna elements comprise:
one or more patch antennas disposed in a first substrate antenna layer in the antenna substrate; and
one or more dipole antennas disposed in a second substrate antenna layer in the antenna substrate adjacent to the first substrate antenna layer.
   18. The package substrate of any of clauses 1 to 17, further comprising:
a second slot-shaped antenna, comprising:
   a second conductive slot disposed in at least one metallization layer among the one or more metallization layers; and
   at least one second antenna feed line comprising at least one second metal interconnect among the one or more metal interconnects of the at least one metallization layer coupled to the second conductive slot.
      19. The package substrate of clause 18, wherein:
the conductive slot is elongated in a first direction; and
the second conductive slot is elongated in a second direction orthogonal to the first direction.
   20. The package substrate of any of clauses 1 to 19, wherein the slot-shaped antenna comprises a 5G antenna.
   21. The package substrate of any of clause 1-20 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
   22. A method of forming an integrated slot-shaped antenna in a package substrate, comprising:
forming one or more metallization layers each comprising one or more metal interconnects;
forming a conductive slot disposed in at least one metallization layer among the one or more metallization layers to form a slot-shaped antenna; and
coupling at least one antenna feed line comprising at least one metal interconnect among the one or more metal interconnects of the at least one metallization layer coupled to the conductive slot.
   23. The method of clause 22, wherein:
forming the conductive slot comprises:
   forming a slot in an opening and in the at least one metallization layer to form at least one side wall in the slot; and
   disposing a metal material in the opening and on at least one side wall to form a conductive side wall in the slot; and
coupling the at least one antenna feed line comprises:
   coupling the at least one antenna feed line to the metal material disposed on the at least one side wall of the slot.
      24. The method of clause 23, wherein forming the slot in the at least one metallization layer comprises forming the slot through each metallization layer among the at least one metallization layer to form the at least one side wall in the slot.
      25. The method of any of clauses 23 and 24, wherein forming the slot comprises drilling in the opening and in the at least one metallization layer.
      26. The method of any of clauses 22 to 25, wherein:
forming the conductive slot comprises:
   forming an opening in the at least one metallization layer;
   forming a slot through the opening and through the at least one metallization layer to form a first side wall through the at least one metallization layer and a second side wall disposed through the at least one metallization layer adjacent to the first side wall;
   disposing a first metal material in the opening and on the first side wall to form a first conductive side wall in the slot; and
   disposing a second metal material in the opening and on the second side wall to form a second conductive side wall in the slot; and
coupling the at least one antenna feed line comprises:
   coupling the at least one antenna feed line to the first metal material disposed on the first side wall of the slot.
      27. The method of any of clauses 22 to 25, wherein:
forming the one or more metallization layers comprising forming the one or more metallization layers in a metallization substrate; and
further comprising:
   coupling a core substrate to the metallization substrate; and
   coupling an antenna substrate to the core substrate; and
wherein.
   forming the conductive slot comprises:
   forming a slot through the at least one metallization layer among the one or more metallization layers in the metallization substrate, the core substrate, and the antenna substrate to form at least one side wall in the slot; and
   disposing a metal material in an opening and on the at least one side wall to form a conductive side wall in the slot.
      28. An integrated circuit (IC) package, comprising:
a package substrate, comprising:
   a metallization substrate comprising one or more metallization layers each comprising one or more metal interconnects; and
   a slot-shaped antenna, comprising:
      a conductive slot disposed in at least one metallization layer among the one or more metallization layers; and
      at least one antenna feed line comprising at least one metal interconnect among the one or more metal interconnects of the at least one metallization layer coupled to the conductive slot; and
an IC die layer coupled to the package substrate, the IC die layer comprising a radio-frequency (RF) IC (RFIC) die comprising a plurality of die interconnects; and
at least one die interconnect among the plurality of die interconnects coupled to the at least one antenna feed line of the slot-shaped antenna.
   29. The IC package of clause 28, wherein the conductive slot is configured to radiate a RF signal received from the at least one antenna feed line from the RFIC die.
   30. The IC package of any of clauses 28 and 29, wherein:
the conductive slot comprises:
   a slot comprising at least one side wall disposed in the at least one metallization layer; and
   a metal material disposed on the at least one side wall; and
the at least one metal interconnect of the one or more metal interconnects of the at least one metallization layer is coupled to the metal material.
   31. The IC package of any of clauses 28 to 30, wherein the package substrate further comprises a metallization substrate comprising the one or more metallization layers each comprising the one or more metal lines.
   32. The IC package of clause 31, wherein the package substrate further comprises a core substrate disposed adjacent to the metallization substrate,
the core substrate comprising a core metallization layer comprising one or more metal interconnects coupled to the one or more metal interconnects in the metallization substrate.
   33. The package substrate of clauses 31 and 32, wherein the package substrate further comprises an antenna substrate comprising one or more antenna elements each coupled to a metal interconnect among the one or more metal interconnects in the metallization substrate.
   34. The IC package of clause 33, wherein the one or more antenna elements comprise:
one or more patch antennas disposed in a first substrate antenna layer in the antenna substrate; and
one or more dipole antennas disposed in a second substrate antenna layer in the antenna substrate adjacent to the first substrate antenna layer.
   35. The IC package of any of clause 28-34 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

What is claimed is:

1. A package substrate, comprising:
one or more metallization layers each comprising one or more metal interconnects; and
a slot-shaped antenna, comprising:
a conductive slot disposed in at least one metallization layer among the one or more metallization layers; and
at least one antenna feed line comprising at least one metal interconnect among the one or more metal interconnects coupled to the conductive slot.

2. The package substrate of claim 1, wherein the conductive slot is configured to radiate a radio-frequency (RF) signal received from the at least one antenna feed line.

3. The package substrate of claim 1, wherein:
the conductive slot comprises:
a slot comprising at least one side wall disposed in the at least one metallization layer; and
a metal material disposed on the at least one side wall; and
the at least one metal interconnect of the one or more metal interconnects of the at least one metallization layer is coupled to the metal material.

4. The package substrate of claim 3, wherein the slot is elongated along an axis parallel to a plane of the at least one metallization layer;
the conductive slot configured to radiate a radio-frequency (RF) signal in a direction orthogonal to a direction of the elongation of the slot.

5. The package substrate of claim 1, wherein:
the conductive slot comprises a slot comprising:
a first conductive side wall, comprising:
a first side wall disposed in the at least one metallization layer; and
a first metal material disposed on the first side wall; and
a second conductive side wall, comprising:
a second side wall disposed in the at least one metallization layer adjacent to the first side wall; and
a second metal material disposed on the second side wall; and
the at least one metal interconnect of the one or more metal interconnects of the at least one metallization layer is coupled to the first metal material.

6. The package substrate of claim 5, wherein the first metal material is not physically coupled to the second metal material.

7. The package substrate of claim 5, wherein the second conductive side wall is configured to be electromagnetically coupled to the first conductive side wall in response to a radio-frequency (RF) signal.

8. The package substrate of claim 1, wherein the conductive slot comprises:
a first end disposed adjacent to a first opening in the one or more metallization layers; and
a second end opposite the first end, the second end adjacent to a second opening in the one or more metallization layers.

9. The package substrate of claim 1, wherein:
the one or more metallization layers are each elongated in a first axis; and
the conductive slot is disposed in the least one metallization layer in a direction orthogonal to the first axis.

10. The package substrate of claim 1, wherein:
the one or more metallization layers comprise a plurality of metallization layers; and
the conductive slot is disposed in at least two (2) metallization layers among the plurality of metallization layers.

11. The package substrate of claim 1, wherein:
the one or more metallization layers comprise a plurality of metallization layers; and
the conductive slot is disposed through each metallization layer among the plurality of metallization layers.

12. The package substrate of claim 1, further comprising a metallization substrate comprising the one or more metallization layers each comprising the one or more metal interconnects.

13. The package substrate of claim 12, further comprising a core substrate disposed adjacent to the metallization substrate,
the core substrate comprising a core metallization layer comprising one or more metal interconnects coupled to the one or more metal interconnects in the metallization substrate.

14. The package substrate of claim 12, further comprising an antenna substrate comprising one or more antenna elements each coupled to a metal interconnect among the one or more metal interconnects in the metallization substrate.

15. The package substrate of claim 14, wherein the one or more antenna elements comprise one or more patch antennas.

16. The package substrate of claim 14, wherein the one or more antenna elements comprise one or more dipole antennas.

17. The package substrate of claim 14, wherein the one or more antenna elements comprise:
one or more patch antennas disposed in a first substrate antenna layer in the antenna substrate; and
one or more dipole antennas disposed in a second substrate antenna layer in the antenna substrate adjacent to the first substrate antenna layer.

18. The package substrate of claim 1, further comprising:
a second slot-shaped antenna, comprising:
a second conductive slot disposed in at least one second metallization layer among the one or more metallization layers; and
at least one second antenna feed line comprising at least one second metal interconnect among the one or more metal interconnects of the at least one second metallization layer coupled to the second conductive slot.

19. The package substrate of claim 18, wherein:
the conductive slot is elongated in a first direction; and
the second conductive slot is elongated in a second direction orthogonal to the first direction.

20. The package substrate of claim 1, wherein the slot-shaped antenna comprises a 5G antenna.

21. The package substrate of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

22. A method of forming an integrated slot-shaped antenna in a package substrate, comprising:
forming one or more metallization layers each comprising one or more metal interconnects;
forming a conductive slot disposed in at least one metallization layer among the one or more metallization layers to form a slot-shaped antenna; and
coupling at least one antenna feed line comprising at least one metal interconnect among the one or more metal interconnects of the at least one metallization layer coupled to the conductive slot.

23. The method of claim 22, wherein:
forming the conductive slot comprises:
forming a slot in an opening and in the at least one metallization layer to form at least one side wall in the slot; and
disposing a metal material in the opening and on at least one side wall to form a conductive side wall in the slot; and
coupling the at least one antenna feed line comprises:
coupling the at least one antenna feed line to the metal material disposed on the at least one side wall of the slot.

24. The method of claim 23, wherein forming the slot in the at least one metallization layer comprises forming the slot through each metallization layer among the at least one metallization layer to form the at least one side wall in the slot.

25. The method of claim 23, wherein forming the slot comprises drilling in the opening and in the at least one metallization layer.

26. The method of claim 22, wherein:
forming the conductive slot comprises:
forming an opening in the at least one metallization layer;
forming a slot through the opening and through the at least one metallization layer to form a first side wall through the at least one metallization layer and a second side wall disposed through the at least one metallization layer adjacent to the first side wall;
disposing a first metal material in the opening and on the first side wall to form a first conductive side wall in the slot; and
disposing a second metal material in the opening and on the second side wall to form a second conductive side wall in the slot; and
coupling the at least one antenna feed line comprises:
coupling the at least one antenna feed line to the first metal material disposed on the first side wall of the slot.

27. The method of claim 22, wherein:
forming the one or more metallization layers comprising forming the one or more metallization layers in a metallization substrate; and
further comprising:
coupling a core substrate to the metallization substrate; and
coupling an antenna substrate to the core substrate; and
wherein:
forming the conductive slot comprises:
forming a slot through the at least one metallization layer among the one or more metallization layers in the metallization substrate, the core substrate, and the antenna substrate to form at least one side wall in the slot; and
disposing a metal material in an opening and on the at least one side wall to form a conductive side wall in the slot.

28. An integrated circuit (IC) package, comprising:
a package substrate, comprising:
a metallization substrate comprising one or more metallization layers each comprising one or more metal interconnects; and
a slot-shaped antenna, comprising:
a conductive slot disposed in at least one metallization layer among the one or more metallization layers; and
at least one antenna feed line comprising at least one metal interconnect among the one or more metal interconnects of the at least one metallization layer coupled to the conductive slot; and
an IC die layer coupled to the package substrate, the IC die layer comprising a radio-frequency (RF) IC (RFIC) die comprising a plurality of die interconnects; and
at least one die interconnect among the plurality of die interconnects coupled to the at least one antenna feed line of the slot-shaped antenna.

29. The IC package of claim 28, wherein the conductive slot is configured to radiate a RF signal received from the at least one antenna feed line from the RFIC die.

30. The IC package of claim 28, wherein:
the conductive slot comprises:
a slot comprising at least one side wall disposed in the at least one metallization layer; and
a metal material disposed on the at least one side wall; and
the at least one metal interconnect of the one or more metal interconnects of the at least one metallization layer is coupled to the metal material.

31. The IC package of claim 28, wherein the package substrate further comprises a metallization substrate comprising the one or more metallization layers each comprising the one or more metal interconnects.

32. The IC package of claim 31, wherein the package substrate further comprises a core substrate disposed adjacent to the metallization substrate,
the core substrate comprising a core metallization layer comprising one or more metal interconnects coupled to the one or more metal interconnects in the metallization substrate.

33. The IC package of claim 31, wherein the package substrate further comprises an antenna substrate comprising one or more antenna elements each coupled to a metal interconnect among the one or more metal interconnects in the metallization substrate.

34. The IC package of claim 33, wherein the one or more antenna elements comprise:
one or more patch antennas disposed in a first substrate antenna layer in the antenna substrate; and
one or more dipole antennas disposed in a second substrate antenna layer in the antenna substrate adjacent to the first substrate antenna layer.

35. The IC package of claim 28 integrated into a device selected from the group consisting of: a set top box; an entertainment unit; a navigation device; a communications device, a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
